(19) United States
(12) Patent Application Publication
(10) Pub. No.: US 2015/0002004 A1
(43) Pub. Date: Jan. 1, 2015

(54) MOUNTING APPARATUS FOR SECURING MEMBER

(71) Applicants: HONG FU JIN PRECISION INDUSTRY (ShenZhen) CO., LTD., Shenzhen (CN); HON HAI PRECISION INDUSTRY CO., LTD., New Taipei (TW)

(72) Inventors: LONG-JUAN WANG, Shenzhen (CN); YA-NI ZHANG, Shenzhen (CN)

(73) Assignees: HONG FU JIN PRECISION INDUSTRY (ShenZhen) CO., LTD., Shenzhen (CN); HON HAI PRECISION INDUSTRY CO., LTD., New Taipei (TW)

(21) Appl. No.: 14/256,477

(22) Filed: Apr. 18, 2014

(30) Foreign Application Priority Data
Jun. 28, 2013 (CN) 2013102641778

(51) Int. Cl. H05K 7/14; H05K 7/12; H05K 7/18; H05K 5/02

(52) U.S. Cl. CPC H05K 7/1429; H05K 5/0217; H05K 7/12; H05K 7/183
USPC 312/223.2

(57) ABSTRACT

A mounting apparatus includes a case and a bracket attached to the case. The case includes a retaining member and a clasping member attached to the retaining member. The retaining member includes a stopping tab and a limiting panel. The clasping member includes a clasping piece. The clasping piece is deformable and engaged with a securing member. The stopping tab and the clasping member are engaged with opposite sides of the securing member to prevent the securing member from moving in a first direction. The limiting panel abuts the securing member to prevent the securing member from moving in a first direction that is substantially perpendicular to the first direction.

### FIELD

The present disclosure relates to mounting apparatuses, and more particularly to a mounting apparatus for securing a securing member used to secure an expansion card.

### BACKGROUND

Computer systems usually include multiple expansion cards secured to a motherboard, such as sound cards, video cards, and graphics cards, for example, for enhancing capabilities of the computer system. Usually, a securing member will be used for assembly or disassembly the expansion cards.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of a mounting apparatus, an expansion card and a securing member in accordance with an embodiment.

FIG. 2 is similar to FIG. 1, but viewed from a different aspect.

FIG. 3 is similar to FIG. 1, and the expansion card and the securing member are secured to a bracket of the mounting apparatus of FIG. 1.

FIG. 4 is an assembled view of the mounting apparatus, the expansion card and the securing member of FIG. 1.

FIG. 5 is an assembled view of the expansion card, the securing member and the bracket of the mounting apparatus of FIG. 1, and the securing member is detached from the bracket.

FIG. 6 is similar to FIG. 5, and the securing member is secured to the bracket.

FIG. 7 is a front view of the expansion card, the securing member and the bracket of FIG. 6.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

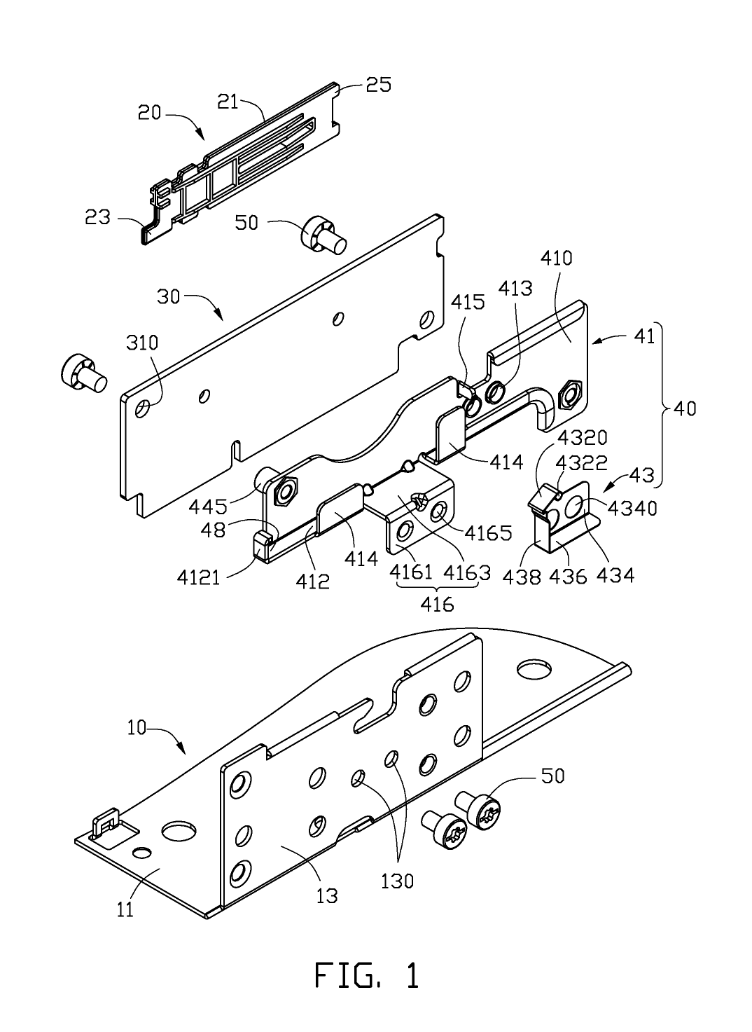

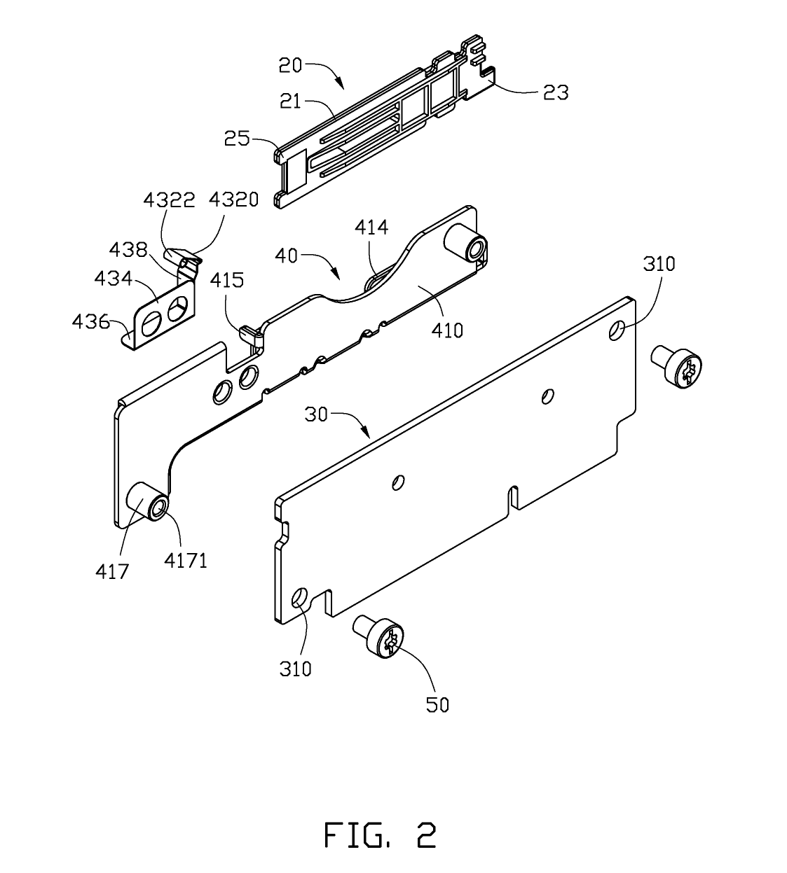

FIGS. 1-2 illustrate a mounting apparatus in accordance with an embodiment. The mounting apparatus comprises a case 10 and a bracket 40 attached to the case 10. An expansion card 30 can be secured to the bracket 40. The mounting apparatus is used to secure a securing member 20, and the securing member 20 is used to detach expansion card 30 from the bracket 40.

The case 10 comprises a bottom plate 11 and a mounting plate 13 connected to the bottom plate 11. In at least one embodiment, the mounting plate 13 is substantially perpendicular to the bottom plate 11. Two mounting holes 130 are defined in the mounting plate 13.

The securing member 20 comprises a main body 21, an inserting portion 23 located on a first end of the main body 21, and a clipping portion 25 located on a second end of the main body 21.

The expansion card 30 can be secured to a motherboard (not shown) and defines two through holes 310.

The bracket 40 comprises a retaining member 41 and a clasping member 43 secured to the retaining member 41. The retaining member 41 comprises a retaining panel 410, a connecting panel 412, two limiting panels 414, and a fixing panel 416. In at least one embodiment, the connecting panel 412 is substantially perpendicular to the retaining panel 410 and the two limiting panels 414, and each of the two limiting panels 414 is substantiallyparallel to theretaining panel 410. The retaining panel 410 defines two retaining posts 413. A blocking tab 415 extends from the retaining panel 410 adjacent to the two retaining posts 413. Two positioning posts 417, each with a positioning hole 4171, are located on the retaining panel 410. The fixing panel 416 located between the two limiting panels 414 and comprises a connectingportion 4161 and a fixing portion 4163 substantially perpendicular to the connecting portion 4161. The connecting portion 4162 is substantiallyperpendicular to the retaining panel 410. Two fixing holes 4165 are defined in the fixing portion 4163 and correspond to the two mounting holes 130. A stopping tab 4121 is located on an end of the connecting panel 412. In at least one embodiment, the stopping tab 4121 is substantiallyperpendicular to the connecting panel 412. In at least one embodiment, the stopping tab 4121 is substantially L-shaped.

The clasping member 43 comprises a securing piece 434, a clasping piece 438, and a connecting piece 436 connected to the securing piece 434 and the clasping piece 438. The securing piece 434 defines two securing holes 4340 corresponding to the two retaining posts 413. A hook 4320, with an operating portion 4322, extends from the top edge of the clasping piece 438. The hook 4320 can be clipped with the clipping portion 25, and the clasping piece 438 is deformable to disengage the hook 4320 from the clipping portion 25 by the operating portion 4322. In at least one embodiment, the hook 4320 is substantially V-shaped.

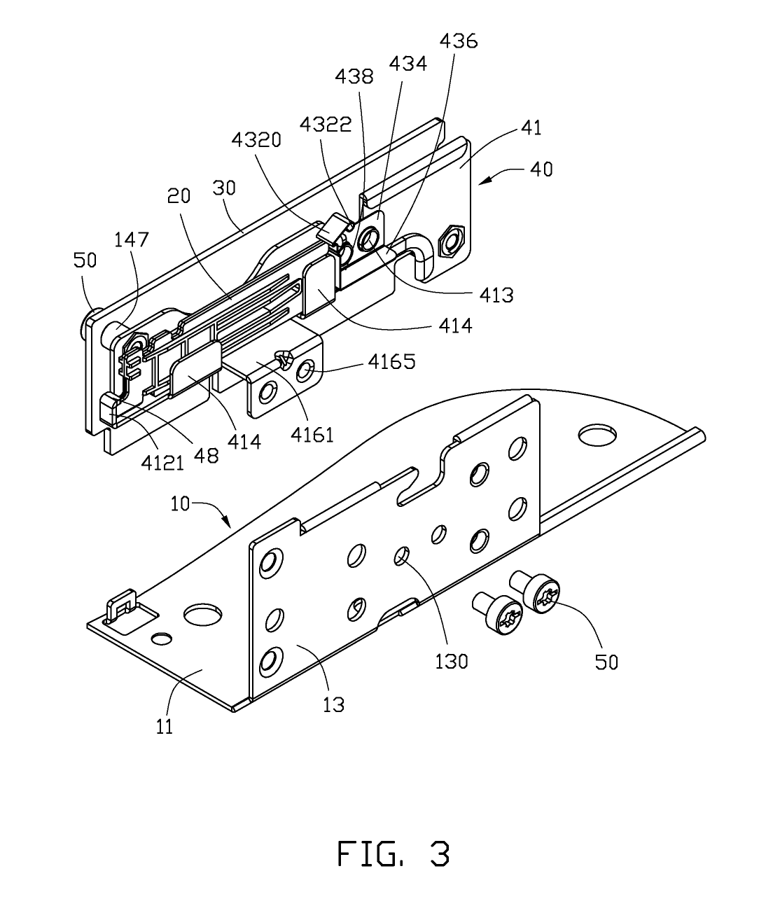

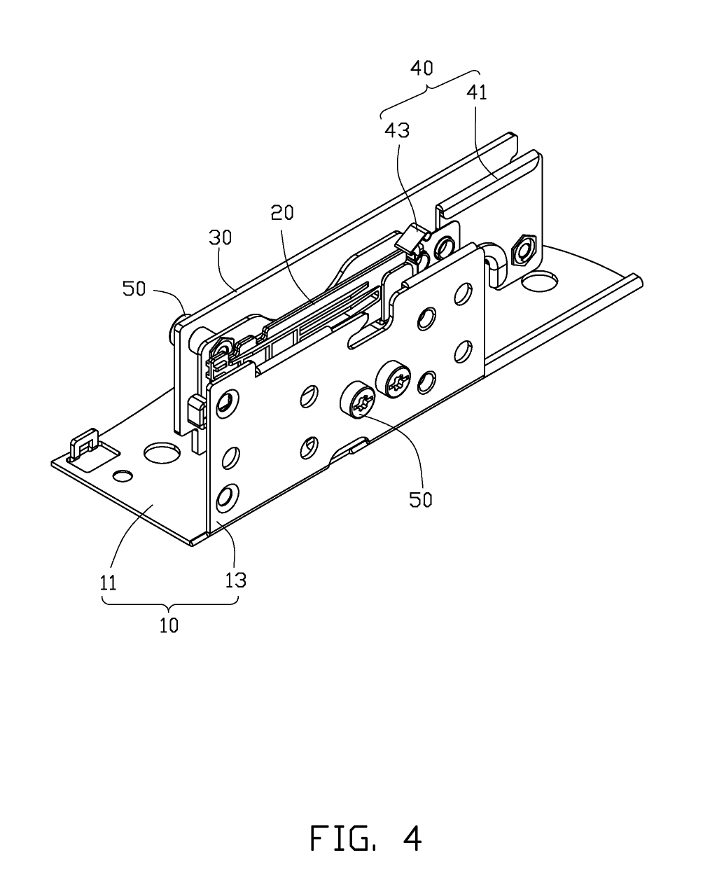

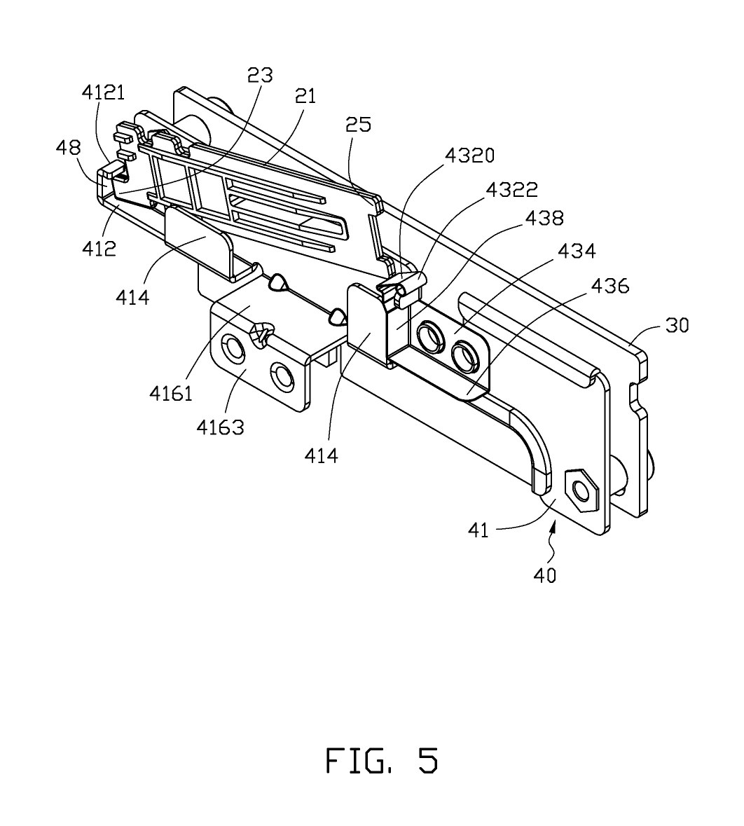

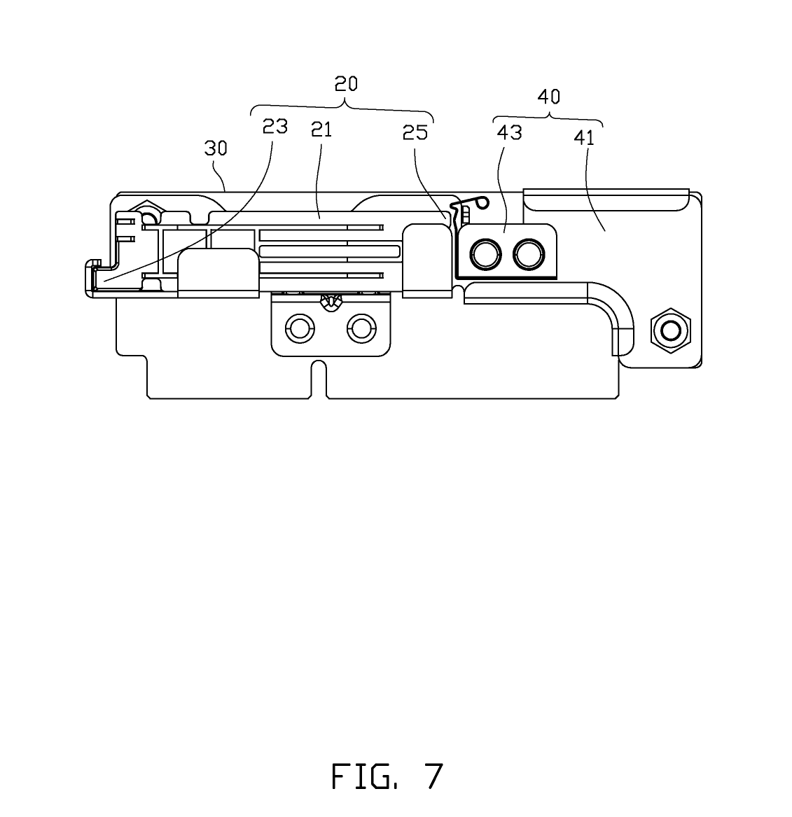

FIGS. 3-7 illustrate assembly of the mounting apparatus of an embodiment. The clasping member 43 abuts the retaining panel 410, and the two securing holes 4340 are aligned with the two retaining posts 413, to secure to the clasping member 43 to the retaining panel 410. The blocking tab 415 abuts the clasping piece 438, to prevent the clasping piece 438 from moving (see FIG. 5). The expansion card 30 abuts the retaining panel 410, the two positioning posts 417 extend through the corresponding two through holes 310. Two fastening members 50 are received in the two positioning holes 4171, to secure the expansion card 30 to the retaining panel 410. The retaining member 41 is located on the bottom panel 11, and the two fixing holes 4165 are aligned with the two mounting holes 130. Another two fastening members 50 are engaged in the two fixing holes 4165 and the two mounting holes 130, securing the retaining member 41 to the case 10.

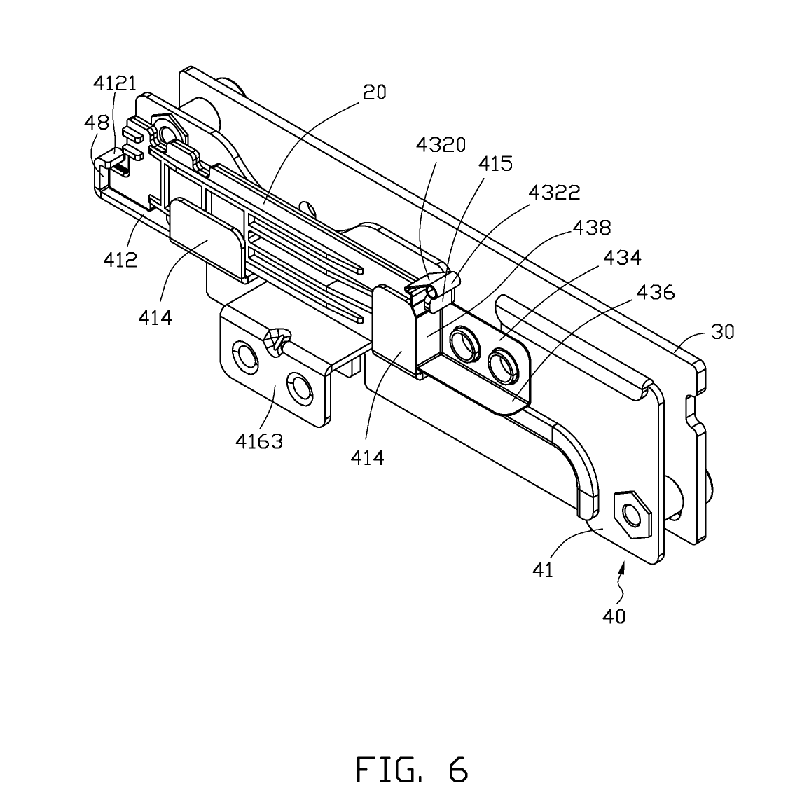

The securing member 20 can be located between the retaining panel 410 and the two limiting panels 414. The securing member 20 is slanted relative to the retaining panel 410 (see FIG. 5), and the inserting portion 23 is engaged with the stopping tab 4121. The clipping portion 25 is blocked by the clasping piece 438. The operating piece 4322 is operated to deform the clasping piece 438 away from the clipping portion 25. The securing member 20 is moved downward. When the securing member 20 abuts the connecting panel 412, the clasping piece 438 is released to clip the hook 4320 with the clipping portion 25 (see FIG. 6). Therefore, the securing member 20 can be received in a receiving space 48 defined by the retaining panel 410, the blocking tab 415, the two limiting panels 414, and the stopping tab 4121. The stopping tab 4121 and the clasping piece 438 together prevent the securing member 20 from moving in a first direction that is substantially parallel to the retaining panel 410, and the two limiting panels 414 together prevent the securing member 20 from moving in a second direction that is substantiallyperpendicular to the first direction.

In disassembly, the operating piece 4322 is operated to deform the clasping piece 438 away from the clipping portion 25, and the hook 4320 is disengaged from the clippingportion 25. The securing member 20 is removed to disengage the inserting portion 23 from the stopping tab 4121. Therefore, the securing member 20 can be removed from the bracket 40 for detaching the expansion card 30.

It is to be understood that even though numerous characteristics and advantages have been set forth in the foregoing description of embodiments, together with details of the structures and functions of the embodiments, the disclosure is illustrative only and changes may be made in detail, including in the matters of shape, size, and arrangement of parts within the principles of the disclosure. The embodiments described herein are illustrative, and should not be construed as limiting the following claims.

What is claimed is:

1. A mounting apparatus comprising:
a case; and
a bracket attached to the case and comprising a retaining member and a clasping member attached to the retaining member; the retaining member comprising a stopping tab and a limiting panel; the clasping member comprising a clasping piece; the clasping piece being deformable and configured to engage with a securing member;
wherein the stopping tab and the clasping member are configured to engage with opposite sides of the securing member, to prevent the securing member from moving in a first direction, and the limiting panel is configured to abut the securing member to prevent the securing member from moving in a first direction that is substantially perpendicular to the first direction.

2. The mounting apparatus of claim 1, wherein the retaining member comprises a retaining panel, and the limiting panel is substantially parallel to the retaining panel.

3. The mounting apparatus of claim 2, wherein the first direction is substantially parallel to the retaining panel.

4. The mounting apparatus of claim 2, wherein the retaining panel comprises a blocking tab, and when the clasping piece is deformed, the clasping piece abuts the blocking tab.

5. The mounting apparatus of claim 2, wherein the retaining member further comprises a connecting panel connected to the retaining panel and the limiting panel, and the stopping tab is located on theconnecting panel.

6. The mounting apparatus of claim 2, wherein the retaining member further comprises a fixing panel connected to the retaining panel, and the case comprises a mounting plate secured to the fixing panel.

7. The mounting apparatus of claim 2, wherein the clasping member further comprises a securing piece and a connecting piece connected to the securing piece and the clasping piece, the securing piece is secure to the retaining panel, and the connecting piece is substantially perpendicular to the clasping piece and the securing piece.

8. The mounting apparatus of claim 1, wherein the blocking tab is substantially L-shaped.

9. The mounting apparatus of claim 1, wherein the clasping piececomprises a hook, and the hook is substantially V-shaped and configured to engage with the securing member.

10. The mounting apparatus of claim 1, wherein the securing member further comprises a positioning post, and the positioning post is configured to secure an expansion card.

11. A mounting apparatus comprising:
a casecomprising a bottom plate and a mounting plate substantiallyperpendicular to the bottom plate; and
a bracket comprising a retaining member and a clasping member attached to the retaining member; the retaining member secured to the mounting plate and comprising a retaining panel, a stopping tab, and a limiting panel; the clasping member comprising a clasping piece; the clasping piece is deformable and configured to engage with a securing member;
wherein the retaining panel, the stopping tab, thelimiting panel, and the clasping member together defines a receiving space, and the receiving space is configured to receive the securing member therein.

12. The mounting apparatus of claim 11, wherein the stopping tab and the clasping member are configured to engaged with opposite sides of the securing member, to prevent the securing member from moving in a first direction, and the limiting panel is configured to abut the securing member to prevent the securing member from moving in a first direction that is substantially perpendicular to the first direction.

13. The mounting apparatus of claim 12, wherein the first direction is substantially parallel to the retaining panel.

14. The mounting apparatus of claim 11, wherein the retaining panel comprises a blocking tab, and when the clasping piece is deformed, the clasping piece abuts the blocking tab.

15. The mounting apparatus of claim 11, wherein the retaining member further comprises a connecting panel connected to the retaining panel and the limiting panel, and the stopping tab is located on theconnecting panel.

16. The mounting apparatus of claim 11, wherein the retaining member further comprises a fixing panel connected to the retaining panel, and the case comprises a mounting plate secured to the fixing panel.

17. The mounting apparatus of claim 11, wherein the clasping member further comprises a securing piece and a connecting piece connected to the securing piece and the clasping piece, the securing piece is secure to the retaining panel, and the connecting piece is substantially perpendicular to the clasping piece and the securing piece.

18. The mounting apparatus of claim 11, wherein the blocking tab is substantially L-shaped.

19. The mounting apparatus of claim 11, wherein the clasping piececomprises a hook, and the hook is substantially V-shaped and configured to engage with the securing member.

20. The mounting apparatus of claim 11, wherein the securing member further comprises a positioning post, and the positioning post is configured to secure an expansion card.
